(19) United States
(12) Patent Application Publication
(10) Pub. No.: US 2017/0144438 A1
(43) Pub. Date: May 25, 2017

(54) WIRING STRUCTURE, MEMS DEVICE, LIQUID EJECTING HEAD, LIQUID EJECTING APPARATUS, METHOD FOR MANUFACTURING MEMS DEVICE, METHOD FOR MANUFACTURING LIQUID EJECTING HEAD AND METHOD FOR MANUFACTURING LIQUID EJECTING APPARATUS

(71) Applicant: SEIKO EPSON CORPORATION, Tokyo (JP)

(72) Inventors: Masumi HAYAKAWA, Chikuma (JP); Takashi KATO, Shenzhen (CN)

(21) Appl. No.: 15/354,864

(22) Filed: Nov. 17, 2016

(30) Foreign Application Priority Data
Nov. 24, 2015 (JP) 2015-228460

(51) Int. Cl. B41J 2/14; B81C 3/00; B81B 7/00

(52) U.S. Cl. CPC B41J 2/1433; B81B 7/0006; B81C 3/001; B81B 2201/052; B81B 2201/057; B81B 2203/0315; B81B 2207/07; B81B 2207/056; B81C 2203/037; B41J 2002/14491

(57) ABSTRACT

A wiring structure includes a connecting terminal array formed on a first substrate and a connected terminal array formed on a second substrate, which are electrically connected, wherein a dummy terminal that is not used for transmission and reception of an electrical signal is provided on at least one end of the connecting terminal array in a terminal arrangement direction, and an anisotropic conductive film containing a conductive particle which is disposed between the first substrate and the second substrate extends to the dummy terminal such that an end of the anisotropic conductive film is located on a surface of the dummy terminal.

The entire disclosure of Japanese Patent Application No: 2015-228460, filed Nov. 24, 2015 is expressly incorporated by reference herein in its entirety.

### BACKGROUND

1. Technical Field

The present invention relates to a wiring structure that connects terminals of a substrate, a MEMS device, a liquid ejecting head, a liquid ejecting apparatus, a method for manufacturing a MEMS device, a method for manufacturing a liquid ejecting head and a method for manufacturing a liquid ejecting apparatus.

2. Related Art

Micro electro mechanical systems (MEMS) devices, which are applied to liquid ejecting apparatuses, display apparatuses or various sensors, may include a substrate having connecting terminals for transmission and reception of an electrical signal between the components which form the MEMS device or between the MEMS device and an external circuit. For example, JP-A-H5-183247 discloses a configuration for a MEMS device applied to a liquid crystal display apparatus, in which terminal outlet sections of the liquid crystal panel for connection to an outer circuit and connecting terminals of a flexible print substrate (FPC) are connected by an anisotropic conductive film. In this configuration, dummy terminals are provided on both ends of the connecting terminals of the FPC in order to prevent disconnection due to stress or the like applied on both outer ends.

In this configuration, a material for the anisotropic conductive film is disposed, for example, on a flexible peeling film (a base film in JP-A-5-183247) at a predetermined thickness. Then, while the anisotropic conductive material is attached on connecting terminals of the substrate, they are heated and pressed by a heat tool (a heat head in JP-A-5-183247) (temporarily press-bonding). After that, only the peeling film is peeled off so as to transfer the anisotropic conductive film onto the connecting terminals of the substrate.

FIG. 17 is a schematic view of a conventional configuration which shows a step of peeling a peeling film 66 after an anisotropic conductive material 65 is press-bonded to the connecting terminals 64 of the substrate 63 (transferring step). In the conventional configuration, an end E1 of the anisotropic conductive film 65 in an arrangement direction of the connecting terminals 64 is located outside the end of the connecting terminal array (an outer end of a dummy terminal 64′) E2, or alternatively, is aligned with the E2. In this configuration, when the peeling film 66 is peeled off from the anisotropic conductive film 65, an adhesive force between the connecting terminals 64 (64′) and the anisotropic conductive film 65 does not sufficiently act on the end E1 of the anisotropic conductive film 65, which should be a starting point of peeling. As a consequence, during peeling of the peeling film 66, the anisotropic conductive film 65 may be peeled off along with the peeling film 66 from the connecting terminals 64 (dummy terminal 64′), which may cause a failure.

### SUMMARY

An advantage of some aspects of the invention is that, a wiring structure, a MEMS device, a liquid ejecting head, a liquid ejecting apparatus, a method for manufacturing a MEMS device, a method for manufacturing a liquid ejecting head and a method for manufacturing a liquid ejecting apparatus are provided in order to prevent an anisotropic conductive film from being peeled off from a connecting terminals in a step of transferring the anisotropic conductive film to the connecting terminals.

According to an aspect of the present invention, a wiring structure includes a connecting terminal array formed on a first substrate and a connected terminal array formed on a second substrate, which are electrically connected, wherein a dummy terminal that is not used for transmission and reception of an electrical signal is provided on at least one end of the connecting terminal array in a terminal arrangement direction, and an anisotropic conductive film containing a conductive particle which is disposed between the first substrate and the second substrate extends to the dummy terminal such that an end of the anisotropic conductive film is located on a surface of the dummy terminal.

According to the present invention, since the end of the anisotropic conductive film is located on the surface of the dummy terminal, an adhesive force between the anisotropic conductive film and the dummy terminal acts on the end of the anisotropic conductive film during peeling of the peeling film from the anisotropic conductive film in a step of transferring the anisotropic conductive film to the connecting terminal array, thereby allowing for reliable peeling of the peeling film from the anisotropic conductive film. Accordingly, a problem of the anisotropic conductive film being peeled off along with the peeling film from the connecting terminal array is prevented.

In the above configuration, it is preferable that a width of the anisotropic conductive film is smaller than a width of the dummy terminal in a direction vertical to the terminal arrangement direction and at least one end of the anisotropic conductive film is located on a surface of the dummy terminal.

According to this configuration, since the end of the anisotropic conductive film in the terminal arrangement direction and the end in the direction vertical to the terminal arrangement direction are respectively located on the surface of the dummy terminal, an adhesive force between the anisotropic conductive film and the dummy terminal acts on the ends of the anisotropic conductive film on the dummy terminals in the respective directions. Accordingly, a problem of the anisotropic conductive film being peeled off along with the peeling film from the connecting terminal array is more reliably prevented.

In the above configuration, it is preferable that an area of the dummy terminal is the same as an area of the largest connecting terminal among a plurality of connecting terminals that form the connecting terminal array.

According to this configuration, a large overlapping area between the anisotropic conductive film and the dummy terminal can be ensured. Accordingly, a problem that the anisotropic conductive film is peeled off along with the peeling film from the connecting terminal array can be more reliably prevented. Further, even if the relative position between the anisotropic conductive film and the substrate terminal array are slightly displaced, the end of the anisotropic conductive film can be prevented from being deviated from the surface of the dummy terminal.

According to another aspect of the present invention, a MEMS device includes a first substrate and a second substrate which are electrically connected by the wiring structure of the above configuration.

According to another aspect of the present invention, a liquid ejecting head includes the MEMS device of the above configuration.

According to another aspect of the present invention, a liquid ejecting apparatus includes the liquid ejecting head of the above configuration.

According to another aspect of the present invention, a method of manufacturing a MEMS device includes: attaching the anisotropic conductive film formed on a flexible peeling film to the first substrate while at least one end of the anisotropic conductive film is located on a surface of the dummy terminal in the terminal arrangement direction of the connecting terminal array; temporarily press-bonding the anisotropic conductive film to the connecting terminal array and the dummy terminal by heating and pressing the anisotropic conductive film between the peeling film and the first substrate by using a heat press-bonding tool; peeling the peeling film from the anisotropic conductive film temporarily press-bonded to the connecting terminal array and the dummy terminal; bonding the first substrate and the second substrate with the anisotropic conductive film interposed therebetween while a relative position between the first substrate and the second substrate are defined so that the connecting terminals of the connecting terminal array correspond to the connected terminals of the connected terminal array; and press-bonding the first substrate and the second substrate by heating and pressing in a direction that sandwiches the anisotropic conductive film by using a heat press-bonding tool.

According to the present invention, since the end of the anisotropic conductive film is located on the surface of the dummy terminal, an adhesive force between the end of the anisotropic conductive film and the dummy terminal reliably acts on the end of the anisotropic conductive film during peeling of the peeling film from the anisotropic conductive film in a step of peeling the peeling film. Accordingly, a problem that the anisotropic conductive film is peeled off from the connecting terminal array without being peeled off from the peeling film is prevented.

According to another aspect of the present invention, a method of manufacturing a liquid ejecting head includes the above method of manufacturing a MEMS device.

According to another aspect of the present invention, a method of manufacturing a liquid ejecting apparatus includes the above method of manufacturing a liquid ejecting head.

### BRIEF DESCRIPTION OF THE DRAWINGS

The invention will be described with reference to the accompanying drawings, wherein like numbers reference like elements.

FIG. 1 is a schematic view which shows a configuration of a liquid ejecting apparatus (printer).

FIG. 2 is a cross sectional view of a MEMS device (recording head).

FIG. 3 is a perspective view of a first substrate (relay substrate).

FIG. 4 is a plan view of a connecting terminal array (substrate terminal array) and a wiring insertion port on the first substrate (relay substrate).

FIG. 5 is a cross sectional view of a head unit.

FIG. 6 is a cross sectional view which shows a connection step of the connecting terminal array (substrate terminal array) and a connected terminal array (mating terminal array).

FIG. 7 is a cross sectional view which shows a connection step of the connecting terminal array (substrate terminal array) and the connected terminal array (mating terminal array).

FIG. 8 is a cross sectional view which shows a connection step of the connecting terminal array (substrate terminal array) and the connected terminal array (mating terminal array).

FIG. 9 is a cross sectional view which shows a connection step of the connecting terminal array (substrate terminal array) and the connected terminal array (mating terminal array).

FIG. 10 is a cross sectional view which shows a connection step of the connecting terminal array (substrate terminal array) and the connected terminal array (mating terminal array).

FIG. 11 is a cross sectional view which shows a connection step of the connecting terminal array (substrate terminal array) and the connected terminal array (mating terminal array).

FIG. 12 is a cross sectional view which shows a connection step of the connecting terminal array (substrate terminal array) and the connected terminal array (mating terminal array).

FIG. 13 is a cross sectional view which shows a step of press-bonding step in a second embodiment.

FIG. 14 is a plan view of a connecting terminal array (substrate terminal array) in a third embodiment.

FIG. 15 is a plan view of a connecting terminal array (substrate terminal array) and a connected terminal array (mating terminal array) in a fourth embodiment.

FIG. 16 is a plan view of a connecting terminal array (substrate terminal array) in a fifth embodiment.

FIG. 17 is a schematic view which shows a step of transferring an anisotropic conductive material to a connecting terminals of a conventional substrate.

### DESCRIPTION OF EXEMPLARY EMBODIMENTS

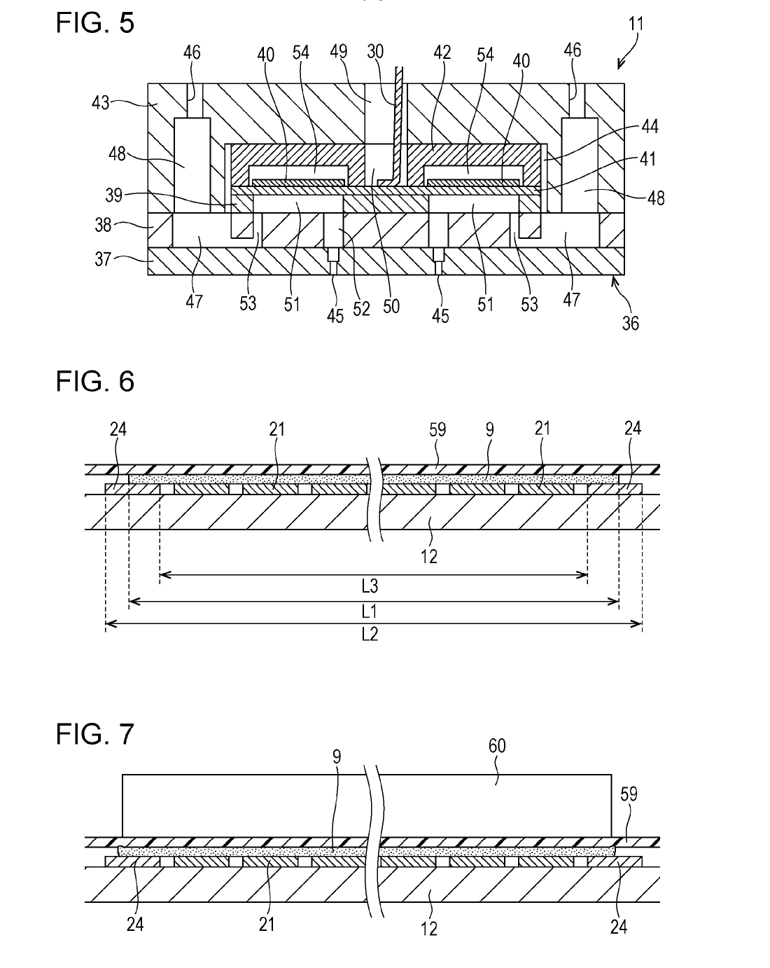

With reference to the drawings, embodiments of the present invention will be described. Although the following embodiments which are described as preferred embodiments of the present invention include various limitations, the scope of the present invention is not construed to be limited to these embodiments unless otherwise specified in the following description. The description will be made by using a recording head (ink jet head; a type of a liquid ejecting head) 2, which is one form of MEMS devices. The recording head 2 is configured such that a drive signal from an external device (printer controller) is applied to a piezoelectric element 40 (see FIG. 5), which is a type of a drive element, via a relay substrate 12, which is a type of a first substrate, and a flexible substrate 30, which is a type of a second substrate.

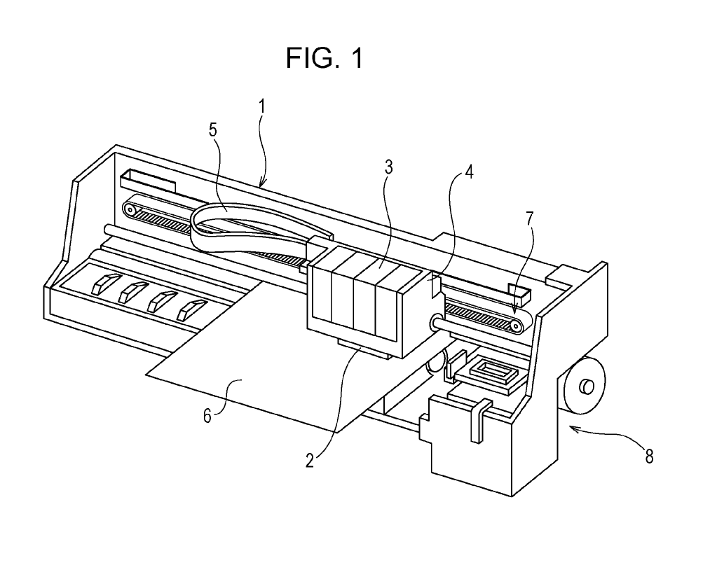

FIG. 1 is a perspective view which shows an internal configuration of a printer 1 (a type of a liquid ejecting apparatus). The printer 1 includes a carriage 4 having the recording head 2 mounted thereon and an ink cartridge 3 as a liquid supply source detachably mounted, a carriage moving mechanism 7 that reciprocates the carriage 4 in a sheet-width direction of a recording paper 6, that is, a main scan direction, and a sheet feeding mechanism 8 that transports the recording paper 6 in a sub-scan direction that is perpendicular to the main scan direction. The carriage 4 is configured to move in the main scan direction by the carriage moving mechanism 7. The printer 1 is configured to reciprocate the carriage 4 while sequentially transporting the recording papers 6 so as to record characters or images on the recording paper 6. Dot pattern data based on the image data, drive signals and various control signals are transmitted from a printer controller, which is not shown in the figure, to the recording head 2 via a flexible flat cable (FFC) 5. Further, the ink cartridge 3 may be disposed on the main body of the printer 1, not on the carriage 4, so that ink in the ink cartridge 3 is supplied to the recording head 2 via an ink supplying tube.

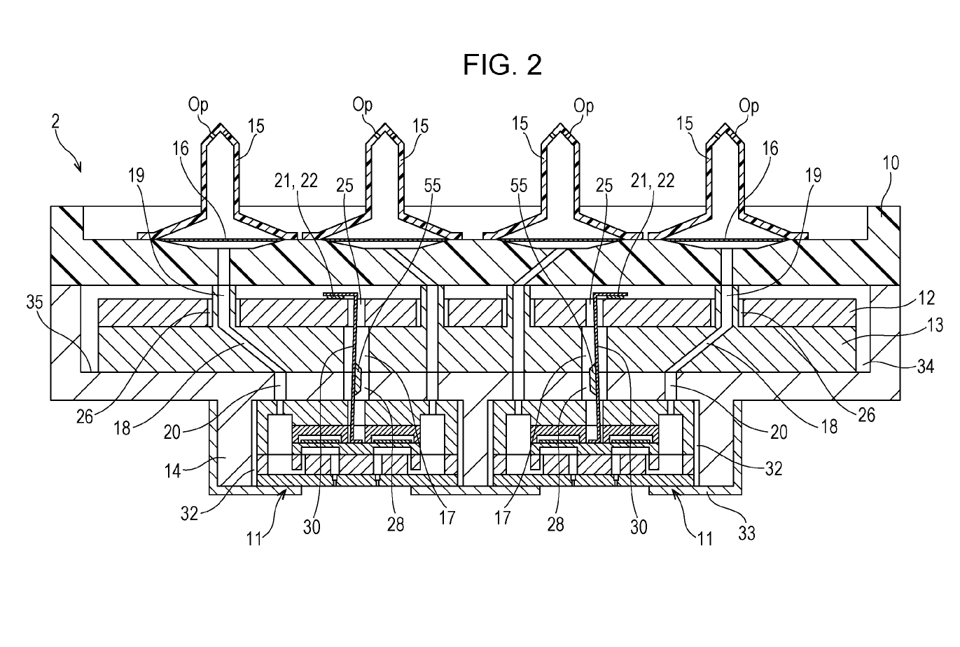

FIG. 2 is a cross sectional view of the recording head 2. The recording head 2 of this embodiment includes an ink introduction substrate 10, a relay substrate 12, a flow path substrate 13, a plurality of head units 11, a holder 14 and the like, which are stacked. For convenience of description, the stacking direction of the components are hereinafter referred to as an up and down direction.

A plurality of ink introduction needles 15 are disposed on the upper surface of the ink introduction substrate 10 with a filter 16 interposed therebetween. Each ink introduction needle 15 is provided for each ink type (color). Both the ink introduction substrate 10 and the ink introduction needles 15 are made of a synthetic resin. Further, the filter 16 is formed of, for example, a braided metal or a thin metal plate having a plurality of holes and is provided for filtering ink in the flow path. The filter 16 captures foreign substances or air bubbles in ink. In this embodiment, the ink cartridge 3 is mounted on the upper surface of the ink introduction substrate 10 so that the ink introduction needle 15 is inserted into the ink cartridge 3. Then, ink in the ink cartridge 3 is introduced into an inner flow path via an opening Op provided on the tip of the ink introduction needle 15. As ink is introduced from the ink introduction needle 15, ink is supplied to the flow path substrate 13 disposed under the ink introduction substrate 10 through the filter 16 via a flow path connecting section 19. Further, the ink introduction needle 15 may not be necessarily inserted into an ink storing member such as a subtank. For example, a so-called foam type configuration can be employed in which porous members such as non-woven clothes or sponges are disposed at the ink inlet portion of the ink introduction substrate 10 and at the ink outlet portion of the ink cartridge 3 or a subtank and both porous members are in contact with each other so as to allow for communication of ink.

The flow path substrate 13 is a substrate having an intermediate flow path 18 that guides ink introduced from the ink introduction needles 15 to the head unit 11. On the upper surface of the flow path substrate 13, the flow path connecting sections 19 of a cylindrical shape are disposed to protrude at the periphery of the opening of the inlet of the intermediate flow path. The flow path connecting section 19 has a height (a length protruding from the upper surface of the flow path substrate 13) which is larger than a thickness of the relay substrate 12 disposed between the ink introduction substrate 10 and the flow path substrate 13. The flow path connecting section 19 communicates with the flow path of the ink introduction substrate 10 so as to allow ink from the ink introduction substrate 10 to be introduced into the intermediate flow path 18. The intermediate flow path 18 is open to the lower surface of the flow path substrate 13 so as to communicate with a communication flow path 20 formed in a partition 35 of the holder 14. Further, a wiring opening 17 is formed in the flow path substrate 13 so as to penetrate in a thickness direction at a position away from the intermediate flow path 18. The wiring opening 17 is a cavity that communicates with a wiring communication port 25 of the relay substrate 12, which will be described later, and communicates with a wiring penetration port 28 formed in the partition 35 of the holder 14. The wiring opening 17 also allows the flexible substrate 30, which will be described later, to be inserted therein.

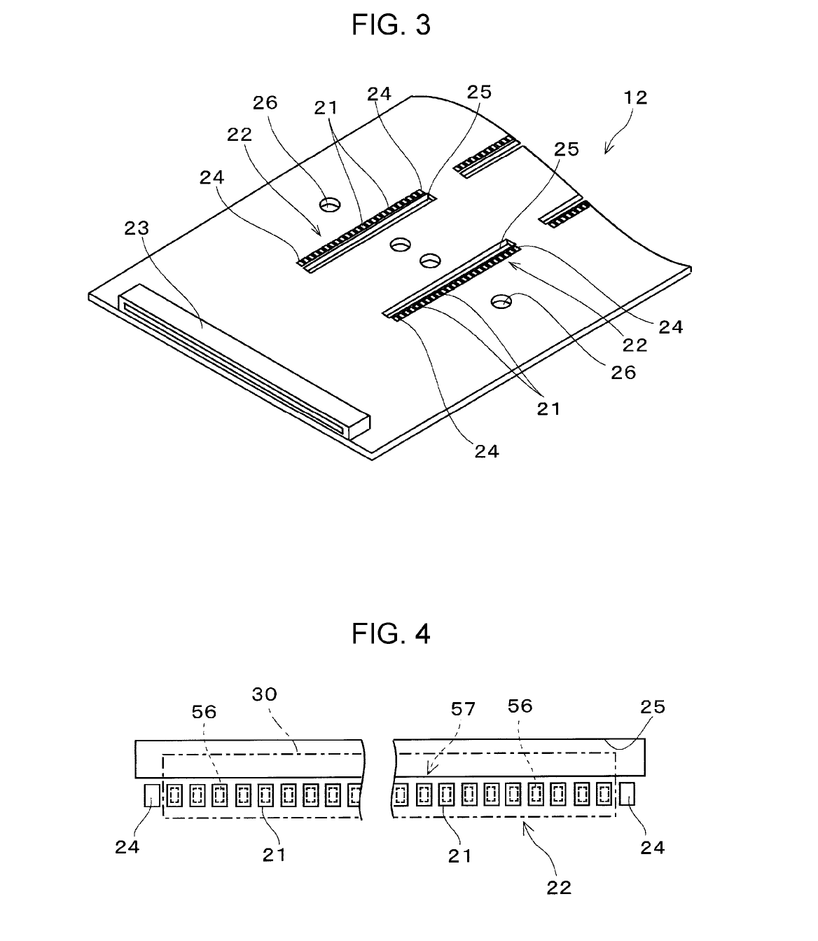

FIG. 3 is a perspective view which shows a configuration of the relay substrate 12 (a type of a first substrate of the present invention). Further, FIG. 4 is a plan view of a substrate terminal array 22 and the wiring insertion port 25 of the relay substrate 12. The relay substrate 12 is a rigid substrate having a wiring pattern for receiving a drive signal or the like from the printer main body via the FFC 5 and supplying the drive signal to the piezoelectric element 40 in the head unit 11 via the flexible substrate 30 (a type of a second substrate of the present invention). The upper surface (the surface opposite to the lower surface of the head unit 11) of the relay substrate 12 is provided with the substrate terminal array 22 (a type of a connecting terminal array of the present invention) made up of a plurality of substrate terminals 21 (a type of a connecting terminal of the present invention). Further, a connector 23 which is connected to the FFC 5 from the printer main body or other electronics are mounted on the relay substrate 12. The relay substrate 12 is configured to receive a drive signal from the printer main body via the FFC 5 connected to the connector 23.

Dummy terminals 24 that are not used for transmission and reception of electrical signals are disposed adjacent to the substrate terminals 21 located on both ends of the substrate terminal array 22 in the terminal arrangement direction. The dummy terminals 24 of this embodiment are made of the same metal as that of the substrate terminals 21 of the substrate terminal array 22, and are formed in the same size as that of the substrate terminals 21. Further, an interval between the dummy terminal 24 and the substrate terminal 21 adjacent to the dummy terminal 24 is the same as an interval between the adjacent substrate terminals 21. Although the dummy terminal 24 of this embodiment is apparently in the same as that of the substrate terminal 21, the dummy terminal 24 is not connected to an electrical signal wire. The dummy terminals 24 perform a function of preventing an anisotropic conductive film 9 from being easily peeled off from the substrate terminals 21 when the anisotropic conductive film (ACF or ACP) 9 is attached to the substrate terminals 21. In this regard, further details will be described later.

In the relay substrate 12, clearance holes 26 are formed at positions corresponding to the flow path connecting sections 19 of the flow path substrate 13 so that the flow path connecting sections 19 are inserted. The clearance hole 26 is a penetrating hole having a diameter slightly larger than the outer diameter of the flow path connecting section 19. Further, a wiring insertion port 25 is formed on the relay substrate 12 so as to penetrate the substrate thickness direction at a position adjacent to the substrate terminal array 22 along the substrate terminal array 22. The wiring insertion port 25 is a hole in which the other end of the flexible substrate 30 is inserted while one end of the flexible substrate 30 is connected to the element terminal of the piezoelectric element 40. The wiring insertion port 25 of this embodiment has an inner dimensions in the longitudinal direction and lateral direction, which are sizes that allow the flexible substrate 30 to be smoothly inserted.

As shown in FIG. 2, a plurality of housing cavities 32 which are spaces that can house the head units 11 are partitioned in the holder 14. The housing cavity 32 is open to the underside (a surface that faces the recording paper 6 in the printer 1 during a printing operation) and the head unit 11 connected to the fixation plate 33 is housed through the opening. The fixation plate 33 is made up of a metal plate member such as a stainless steel. When a nozzle plate 37 of each head unit 11 is connected to the fixation plate 33, the height direction of the head units 11 (position in a direction vertical to the nozzle plate 37) is defined. In an upper part of the holder 14 relative to the housing cavity 32, a substrate mounting portion 34 is provided. On the substrate mounting portion 34, the flow path substrate 13 and the relay substrate 12 are disposed. The substrate mounting portion 34 and the housing cavity 32 are separated from each other by the partition 35 such that the upper surface of the partition 35 serves as a substrate mounting surface. The communication flow path 20 and the wiring penetration port 28 are formed in the partition 35 so as to penetrate in a thickness direction. When the head unit 11 is housed in position in the housing cavity 32, an introduction inlet port 46 of the head unit 11 (see FIG. 5) communicates with the communication flow path 20 and a wiring cavity 49 of the head unit 11 (see FIG. 5) communicates with the wiring penetration port 28.

FIG. 5 is a cross sectional view which shows an inner configuration of the head unit 11. The head unit 11 of this embodiment includes an ejection unit 36 which is made up of a stack of the nozzle plate 37, a communication substrate 38, a pressure chamber forming substrate 39, a vibration plate 41, the piezoelectric element 40 and a protective substrate 42. The ejection unit 36 is mounted on a unit case 43. The unit case 43 is a member having the introduction inlet port 46 that communicates with the communication flow path 20 formed in the partition 35 of the holder 14 so as to allow ink to be introduced from the ink introduction needle 15, and an introduction path 48 that introduces ink introduced from the introduction inlet port 46 to a common liquid chamber 47. A wiring cavity 49 is formed at the center of the unit case 43 in plan view. An upper opening of the wiring cavity 49 communicates with the wiring penetration port 28 and a lower opening of the wiring cavity 49 communicates with a wiring connection cavity 50 of the protective substrate 42, which will be described later. Further, an accommodation cavity 44 is formed on the underside of the unit case 43. The accommodation cavity 44 is recessed in a cuboid shape from the lower surface of the unit case 43 to a middle point in a height direction of the unit case 43. The accommodating cavity 44 is formed to accommodate the pressure chamber forming substrate 39, the vibration plate 41, the piezoelectric element 40 and the protective substrate 42 of the ejection unit 36. In this state, the lower surface of the unit case 43 is connected to the top surface of the communication substrate 38 of the ejection unit 36.

The pressure chamber forming substrate 39 of this embodiment is formed of a silicon monocrystal substrate (hereinafter, simply referred to as a silicon substrate). In the pressure chamber forming substrate 39, a plurality of pressure chamber cavities that partition a pressure chamber 51 corresponding to the nozzles 45 of the nozzle plate 37 are formed by anisotropic etching. An opening on one side (on the upper surface) of the pressure chamber cavity of the pressure chamber forming substrate 39 is sealed by a vibration plate 41. Further, the communication substrate 38 is connected to a surface of the pressure chamber forming substrate 39 opposite from the vibration plate 41 such that the communication substrate 38 seals the other opening of the pressure chamber cavity. Accordingly, the pressure chamber 51 is formed by partitioning. Here, a portion of the upper opening of the pressure chamber 51 which is sealed by the vibration plate 41 is a flexible surface that oscillates by driving of the piezoelectric element 40.

The pressure chamber 51 of this embodiment is an elongated cavity which extends in a direction perpendicular to an arrangement direction the nozzles 45. One end of the pressure chamber 51 in the second direction communicates with the nozzle 45 via a nozzle communication port 52 of the communication substrate 38. Further, the other end of the pressure chamber 51 in the second direction communicates with the common liquid chamber 47 via an individual communication port 53 of the communication substrate 38. A plurality of pressure chambers 51 are arranged in parallel so as to correspond to the respective nozzles 45. The communication substrate 38 is a plate member made of a silicon substrate, similarly to the pressure chamber forming substrate 39. In the communication substrate 38, a cavity serving as the common liquid chamber 47 (also referred to as a reservoir or a manifold) which is provided in common for a plurality of pressure chambers 51 of the pressure chamber forming substrate 39 is formed by anisotropic etching. The common liquid chamber 47 is an elongated cavity which extends along the arrangement direction of the pressure chambers 51. Each pressure chamber 51 communicate with the common liquid chamber 47 via the individual communication port 53.

The nozzle plate 37 is a plate member on which a plurality of nozzles 45 are disposed in array. In this embodiment, a plurality of nozzles 45 that form a nozzle row are arranged at a pitch which corresponds to a dot forming density. The nozzle plate 37 of this embodiment is formed of a silicon substrate, and the cylindrically shaped nozzles 45 are formed on the substrate by dry etching. In the ejection unit 36 of this embodiment, an ink flow path is formed so as to extend from the common liquid chamber 47 to the nozzles 45 via the individual communication port 53, the pressure chamber 51 and the nozzle communication port 52.

The vibration plate 41 formed on the upper surface of the pressure chamber forming substrate 39 is formed of, for example, a silicon dioxide material with a thickness of approximately 1 μm. Further, an insulating film, which is not shown in the figure, is formed on the vibration plate 41. The insulating film is made of, for example, zirconium oxide. The piezoelectric elements 40 are respectively formed at positions corresponding to the pressure chambers 51 on the vibration plate 41 and the insulating film. On the piezoelectric element 40, the vibration plate 41 and the insulating film of this embodiment, a lower electrode film made of a metal, a piezoelectric layer made of lead zirconate titanate (PZT) or the like, and an upper electrode film made of a metal are sequentially stacked (none of these is shown in the figure). In this configuration, one of the upper electrode film and the lower electrode film serves as a common electrode and the other serves as an individual electrode. Further, the electrode film which serves as an individual electrode and the piezoelectric layer are patterned for each pressure chamber 51.

A protective substrate 42 is disposed on the upper surface of the communication substrate 38 on which the pressure chamber forming substrate 39 and the piezoelectric element 40 are mounted. The protective substrate 42 is made of a glass, ceramics material, silicon monocrystal substrate, metal, synthetic resins or the like. A recess 54 is formed in the protective substrate 42 in an area which faces the piezoelectric element 40. The recess 54 has a size that does not interfere with driving of the piezoelectric element 40. Further, a wiring connection cavity 50 is formed at the center of the protective substrate 42 so as to penetrate in the substrate thickness direction. In the wiring connection cavity 50, an element terminal of the piezoelectric element 40 and one end of the flexible substrate 30 are disposed as described above.

The flexible substrate 30 (a type of a second substrate of the present invention) is a chip on film (COF) type wiring substrate on which a drive IC 55 (see FIG. 2) that controls application of drive voltage to the piezoelectric element 40 is mounted on one surface of the rectangular peeling film made of polyimide or the like and the wiring pattern connected to the drive IC 55 is formed. Further, on one end of the flexible substrate 30 (lower end in FIG. 2), one of the ends of a plurality of wiring terminals are arranged so as to correspond to element terminals of the piezoelectric element 40. Further, on the other end of the flexible substrate 30 (see FIG. 4), a mating terminal array 57 (a type of a connected terminal array of the present invention) made up of a plurality of mating terminals 56 (a type of a connected terminal of the present invention) connected to the substrate terminal 21 of the relay substrate 12 is provided. In the flexible substrate 30, the surface of the wiring pattern other than the wiring terminal and the drive IC 55 is covered by a solder resist.

While one end of the wiring terminal is electrically connected to the element terminal of the piezoelectric element 40 in the wiring connection cavity 50 of the protective substrate 42, the other end of the flexible substrate 30 is inserted into the wiring insertion port 25 from the underside of the relay substrate 12 via the wiring cavity 49 of the unit case 26, the wiring cavity 49 of the protective substrate 24, the wiring penetration port 28 of the holder 14 and the wiring opening 17 of the flow path substrate 13, and is led out onto the upper surface of the relay substrate 12 and bent toward the substrate terminal array 22. The mating terminal array 57 made up of a plurality of mating terminals 56 disposed on the other end of the flexible substrate 30 is electrically connected to the substrate terminals 21 of the substrate terminal array 22 via the anisotropic conductive film 9 which contains the heat-curable resin and conductive particle.

When a drive signal (drive voltage) is applied to the piezoelectric element 40 via the relay substrate 12 and the flexible substrate 30, a piezoelectric active portion of the piezoelectric element 40 flexibly deforms in response to change in applied voltage and thus causes a flexible surface that forms one surface of the pressure chamber 51, that is, the vibration plate 41 to move in the direction toward the nozzle 45 or away from the nozzle 45. Accordingly, ink in the pressure chamber 51 is subject to pressure change so that ink is discharged from the nozzle 45 by using this pressure change.

Next, in a manufacturing process of the recording head 2, which is one form of the MEMS device (which is also a manufacturing process of the liquid ejecting head, and is included in a manufacturing process of the printer 1 as a liquid ejecting apparatus), a connection process of the substrate terminal 21 of the relay substrate 12 and the mating terminal 56 of the flexible substrate 30 will be specifically described. In that process, an attaching step, a temporarily press-bonding step and a peeling step described below correspond to a transferring step of the anisotropic conductive film 9 to the substrate terminal 21. As described above, the substrate terminals 21 and the mating terminals 56 are electrically connected by using the anisotropic conductive film 9. First, as shown in FIG. 6, the anisotropic conductive film 9 formed on the peeling film 59 having flexibility such as polyethylene terephthalate (PET) is attached to the substrate terminal array 22 of the relay substrate 21 with a relative position defined (attaching step). Here, in an arrangement direction of the substrate terminal 21 (hereinafter, referred to as a first direction as appropriate), a total length L1 of the anisotropic conductive film 9 is smaller than a distance L2 from an outer end (edge) of the dummy terminal 24 on one end of the substrate terminal array 22 in the first direction to an outer end of the dummy terminal 24 on the other end, and, larger than a distance L3 from an inner end of the dummy terminal 24 on one end of the substrate terminal array 22 in the first direction to an inner end of the dummy terminal 24 on the other end. Accordingly, when the anisotropic conductive film 9 is attached with a relative position to the substrate terminal array 22 of the relay substrate 21 defined, both ends of the anisotropic conductive film 9 in the first direction are respectively located on the surface of the dummy terminals 24 on both ends of the substrate terminal array 22.

In this embodiment, the size of the anisotropic conductive film 9 in the width direction (a second direction perpendicular to the first direction, which is the terminal arrangement direction) is the same as the size of the substrate terminals 21 in the second direction. While the anisotropic conductive film 9 is attached in position to the substrate terminal array 22 as described above, the anisotropic conductive film 9 is heated and pressed by a heat tool 60 (heat press-bonding tool) pressed against the peeling film 59 toward the relay substrate 12 so that the anisotropic conductive film 9 is temporarily press-bonded to the substrate terminals 21 and the dummy terminals 24 as shown in FIG. 7 (temporarily press-bonding step). In so doing, the surface of the anisotropic conductive film 9 is melt depending on the degree of heat and pressure applied by the heat tool 60. Accordingly, at the point of temporarily press-bonding, the anisotropic conductive film 9 still has flexibility. Further, the size of the heat tool 60 in the first direction is the same as the total length L1 of the anisotropic conductive film 9.

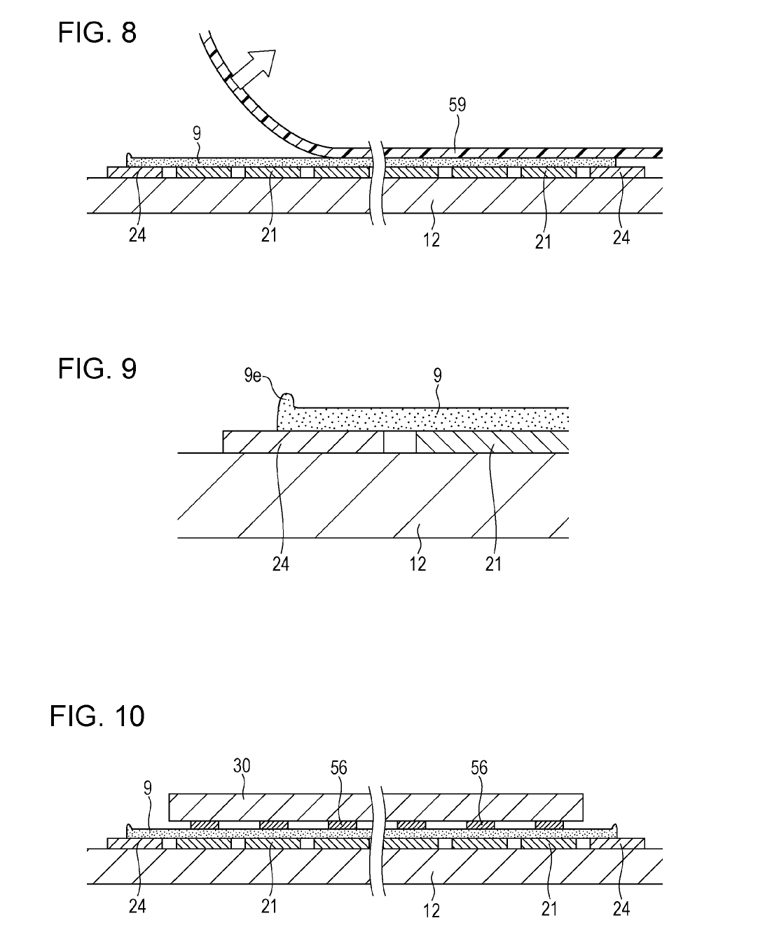

Then, the peeling film 59 is peeled off from the anisotropic conductive film 9 which is temporarily press-bonded to the substrate terminals 21 and the dummy terminals 24 (peeling step). Here, since the end of the anisotropic conductive film 9 in the terminal arrangement direction is located on the surface of the dummy terminal 24, adhesive force between the end of the anisotropic conductive film 9 and the dummy terminal 24 resists to a peeling force of the peeling film 59. Accordingly, as shown in FIG. 8, the peeling film 59 is peeled off from the anisotropic conductive film 9 starting from the end of the anisotropic conductive film 9 on the surface of the dummy terminal 24 in the first direction, while the anisotropic conductive film 9 remains attached to the substrate terminals 21. As described above, since the end of the anisotropic conductive film 9 in the first direction is located on the surface of the dummy terminal 24, an adhesive force between the end of the anisotropic conductive film 9 and the dummy terminal 24 more reliably acts on the end of the anisotropic conductive film 9 during peeling of the peeling film 59. Accordingly, the peeling film 59 is reliably peeled off from the anisotropic conductive film 9 starting from the end of the anisotropic conductive film 9. Accordingly, a problem that the anisotropic conductive film 9 is peeled off along with the peeling film 59 from the substrate terminals 21 is prevented. As a result, yield can be improved. As shown in FIG. 9, since an end 9e of the anisotropic conductive film 9 on the surface of the dummy terminal 24 is pressed and compressed by the heat tool 59 pressed against the dummy terminal 24 after the peeling film 59 is peeled off, the end 9e slightly bulges toward outside in the first direction from an area overlapping the heat tool 59 and warps back in a direction opposite to the compression direction. This warpage of the end of the anisotropic conductive film 9 causes a gap between the end of the anisotropic conductive film 9 and the peeling film 59. Accordingly, the peeling film 59 can be easily peeled off from the anisotropic conductive film 9 starting from the end of the anisotropic conductive film 9. Since such warpages are actively formed on the end of the anisotropic conductive film 9, the heat tool 60 may have a size in the first direction slightly smaller than the total length L1 of the anisotropic conductive film 9.

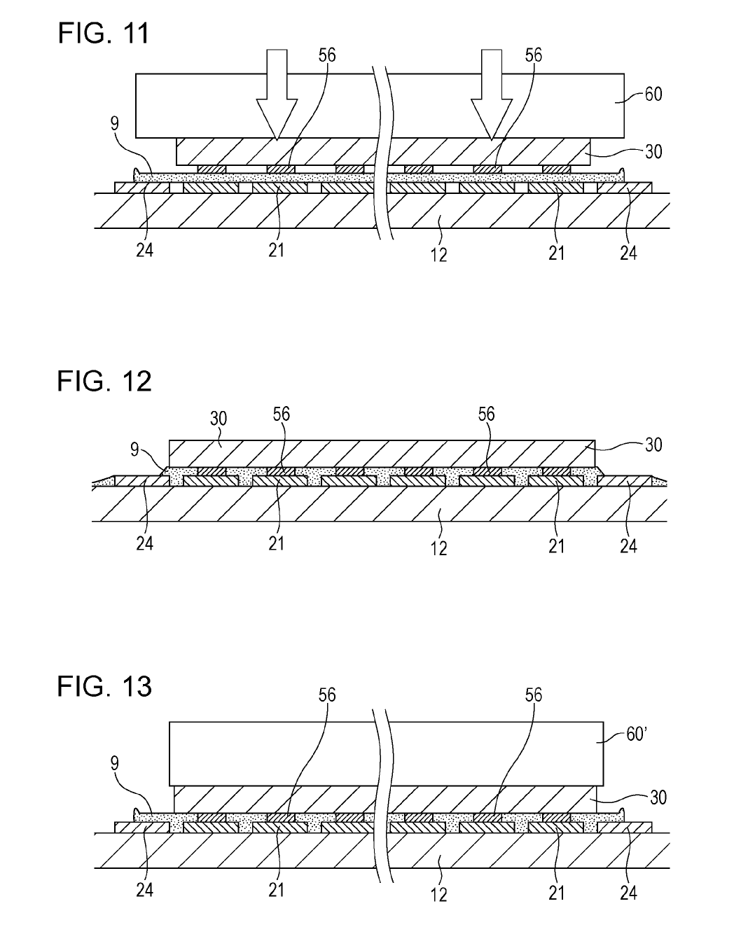

As shown in FIG. 10, while the anisotropic conductive film 9 is temporarily press-bonded to the substrate terminal 21, the orientation of the mating terminal 56 of the flexible substrate 30 is aligned with the substrate terminals 21 of the relay substrate 12. While a relative position of the relay substrate 12 to the flexible substrate 30 is defined so that each of the respective substrate terminals 21 correspond to the respective mating terminals 56 one by one, the relay substrate 12 and the flexible substrate 30 are bonded to each other with the anisotropic conductive film 9 interposed therebetween (bonding step). Subsequently, as shown in FIG. 11, the flexible substrate 30 is heated and pressed by the heat tool 60 toward the relay substrate 12 so that the flexible substrate 30 is press-bonded to the relay substrate 12 (press-bonding step). Then, as shown in FIG. 12, the mating terminals 56 of the flexible substrate 30 are depressed while pressing against the anisotropic conductive film 9 which is softened by heat so as to abut the corresponding substrate terminals 21. A load from the heat tool 60 is concentrated to an overlapping area of the mating terminals 56 and the substrate terminals 21 and thus the conductive particles (not shown) in this area of the anisotropic conductive film 9 are collapsed and overlapped each other. As a result, the mating terminals 56 and the substrate terminals 21 are electrically connected. On the other hand, thermal press-bonding in a portion which does not need electric conduction can be achieved by a load smaller than that in a portion which needs electric conduction. Accordingly, the heat-curable resin of the anisotropic conductive film 9 can be cured while ensuring the thickness, thereby achieving a sufficient bonding strength and an electrical insulation. In this embodiment, the anisotropic conductive film 9 on the dummy terminal 24 is melt by heat from the heat tool 60 in the press-bonding step and flowed out from the surface of the dummy terminal 24, and accordingly, hardly remains on the surface of the dummy terminal 24.

FIG. 13 is a view which shows the press-bonding step in the second embodiment. In the first embodiment, a configuration has been described in which the anisotropic conductive film 9 on the dummy terminal 24 flows out from the surface of the dummy terminal 24 and does not remain thereon. However, depending on the conditions such as a shape, temperature and pressurizing time of the heat tool 60′, the anisotropic conductive film 9 may remain on the surface of the dummy terminal 24. That is, in this case, the anisotropic conductive film 9 containing conductive particles disposed between the relay substrate 12 and the flexible substrate 30 extends to the dummy terminal 24 such that the end of the anisotropic conductive film 9 is disposed on the surface of the dummy terminal 25. In this embodiment, a size of the heat tool 60′ in the first direction is larger than the distance between one end and the other end of the substrate terminal array 22 in the first direction, and, smaller than the distance from an inner end of the dummy terminal 24 on one end of the substrate terminal array 22 in the first direction and an inner end of the dummy terminal 24 on the other end. Accordingly, the heat tool 60′ is configured so as not to overlap the dummy terminal 24 in plan view in the press-bonding step. As a result, in the press-bonding step, heat from the heat tool 60′ is prevented from being transferred to the anisotropic conductive film 9 on the dummy terminal 24. This configuration allows the anisotropic conductive film 9 on the surface of the dummy terminal 24 to remain as it is on the surface of the dummy terminal 24 without being melted. With this configuration of this embodiment, a problem that the anisotropic conductive film 9 on the dummy terminal 24 flows out from the top of the dummy terminal 24 and is adhered to an unintentional position and thus causes short circuit can be prevented.

FIG. 14 is a plan view which shows a configuration of the substrate terminals 21 and the dummy terminals 24 on the relay substrate 12 in a third embodiment. In the first embodiment, a size of the dummy terminal 24 in the second direction (up and down direction in FIG. 14) is the same as a size of the substrate terminals 21 in the second direction. However, in this embodiment, a size W1 of the dummy terminal 24 in the second direction is larger than a size W2 of the substrate terminals 21 in the second direction. The other configurations are the same as those of the first embodiment. At least one of both ends of the dummy terminal 24 in the second direction in this embodiment is located outside to the end of the substrate terminal 21 in the second direction. On the other hand, a size (width) of the anisotropic conductive film 9 in the second direction is the same as the size W2 of the substrate terminals 21 in the second direction. Further, similarly to the case of the first embodiment, a size (total length) L1 of the anisotropic conductive film 9 in the first direction is smaller than a distance L2 from an outer end of the dummy terminal 24 on one end in the first direction to an outer end of the dummy terminal 24 on the other end, and larger than a distance L3 from an inner end of the dummy terminal 24 on one end of the substrate terminal array 22 in the first direction to an inner end of the dummy terminal 24 on the other end. Accordingly, when the anisotropic conductive film 9 is attached with a relative position to the substrate terminal array 22 of the relay substrate 21 defined, the end of the anisotropic conductive film 9 in the first direction and the end in the second direction are respectively located on the surface of the dummy terminals 24. In the configuration of this embodiment, the adhesive force between the anisotropic conductive film 9 and the dummy terminal 24 reliably acts on the end of the anisotropic conductive film 9 in the first direction and the second direction on the surface of the dummy terminal 24 during peeling of the peeling film 59. Accordingly, a problem that the anisotropic conductive film 9 is peeled off along with the peeling film 59 from the substrate terminals 21 is more reliably prevented.

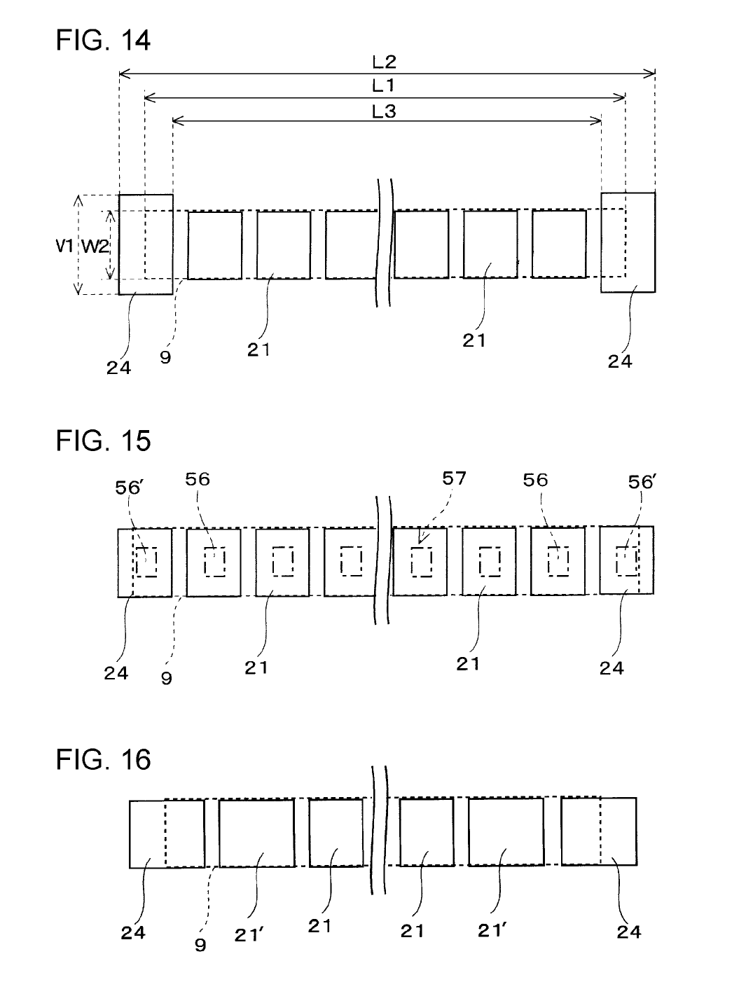

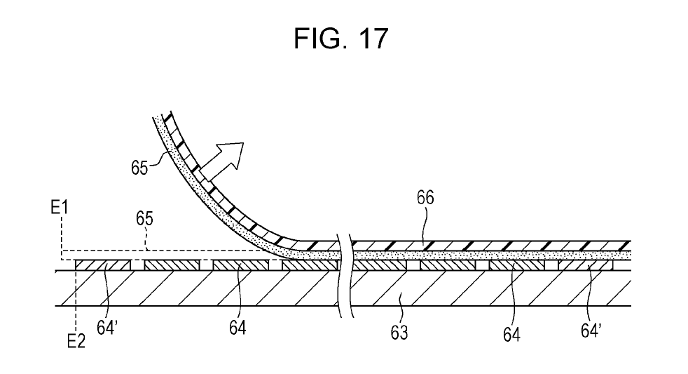

FIG. 15 is a plan view which shows a configuration of the substrate terminals 21 and the dummy terminals 24 on the relay substrate 12 in a fourth embodiment. While a configuration in the above embodiments has been described as the dummy terminal 24 being not connected to the mating terminal 56 of the flexible substrate 30, the invention is not limited thereto. This embodiment differs from the above embodiments in that the dummy mating terminals 56′ which correspond to the dummy terminals 24 are provided on both ends of the mating terminal array 57 of the flexible substrate 30 in the first direction. The dummy mating terminal 56′ is also a terminal that is not used for transmission and reception of an electrical signal. The other configurations are the same as those of the first embodiment. In this embodiment, the dummy mating terminals 56′ are electrically connected to the dummy terminals 24 via the anisotropic conductive film 9. Accordingly, even in the case where an external force is applied to a connection between the substrate terminal array 22 and the mating terminal array 57, a problem of separation between the substrate terminals 21 and the mating terminals 56 can be prevented since their connection is reinforced by connection between the dummy mating terminals 56′ and the dummy terminals 24.

FIG. 16 is a plan view which shows a configuration of the substrate terminals 21 and the dummy terminals 24 on the relay substrate 12 in a fifth embodiment. Of the substrate terminals 21 which form the substrate terminal array 22, the substrate terminals 21′ located on both ends in the first direction are terminals for the common electrode of the piezoelectric element 40. In the present embodiment, an area (surface area) of the substrate terminal 21′ is larger than that of the other substrate terminals 21 due to the size in the first direction being larger than that of the other substrate terminals 21. Further, the surface area of the dummy terminal 24 is also the same as the surface area of the substrate terminal 21′ which is largest in the substrate terminal 21. With this configuration, a large overlapping area between the anisotropic conductive film 9 and the dummy terminal 24 can be ensured. Accordingly, a problem that the anisotropic conductive film 9 is peeled along with the peeling film 59 from the connecting terminal array 22 can be more reliably prevented. Further, even if the relative position between the anisotropic conductive film 9 and the substrate terminal array 22 are slightly displaced, the end of the anisotropic conductive film 9 can be prevented from being deviated from the surface of the dummy terminal 24.

Although the flexible substrate 30 has been described in the above embodiment as a COF type having the drive IC 55, the invention is not limited thereto. For example, the present invention can be applied to a configuration in which the drive IC 55 is provided on the protective substrate 42, not on the flexible substrate 30.

Further, the wiring structure of the present invention can be applied to various MEMS devices, not only to the recording head 2, as long as the connected terminal array of the second substrate is electrically connected to the connecting terminal array formed on the first substrate. For example, it can be applied to a configuration in which a drive signal from an external device of the MEMS device is applied to the drive element via the first substrate and the second substrate so as to drive the drive element, or alternatively, an output signal from a drive element which serves as a sensor is transmitted to the external device of the MEMS device via the first substrate and the second substrate.

Although the ink jet recording head 2 has been described as an example of the liquid ejection head in the above embodiment, the invention can be applied to the other liquid ejecting heads. For example, the present invention can be applied to color material ejection heads used for manufacturing color filters for liquid crystal displays and the like, electrode material ejection heads used for manufacturing electrodes for organic electroluminescence (EL) displays, field emission displays (FEDs) and the like, and bioorganic ejection heads used for manufacturing biochips (biochemistry element) and the like. In the color material ejecting head for a display manufacturing device, solution of color materials of red (R), green (G) and blue (B) as a type of liquid is ejected. Further, in the electrode material ejecting head for an electrode manufacturing apparatus, a liquid electrode material as a type of liquid is ejected, and in the bioorganic ejecting head for a chip manufacturing apparatus, solution of bioorganics as a type of liquid is ejected.

What is claimed is:

1. A wiring structure comprising: a connecting terminal array formed on a first substrate; and a connected terminal array formed on a second substrate, which are electrically connected, wherein
a dummy terminal that is not used for transmission and reception of an electrical signal is provided on at least one end of the connecting terminal array in a terminal arrangement direction, and
an anisotropic conductive film containing a conductive particle which is disposed between the first substrate and the second substrate extends to the dummy terminal such that an end of the anisotropic conductive film is located on a surface of the dummy terminal.

2. The wiring structure according to claim 1, wherein a width of the anisotropic conductive film is smaller than a width of the dummy terminal in a direction vertical to the terminal arrangement direction and at least one end of the anisotropic conductive film is located on a surface of the dummy terminal.

3. The wiring structure according to claim 1, wherein an area of the dummy terminal is the same as an area of a largest connecting terminal among a plurality of connecting terminals that form the connecting terminal array.

4. A MEMS device comprising: a first substrate; and a second substrate, which are electrically connected by the wiring structure according to claim 1.

5. A MEMS device comprising: a first substrate; and a second substrate, which are electrically connected by the wiring structure according to claim 2.

6. A MEMS device comprising: a first substrate; and a second substrate, which are electrically connected by the wiring structure according to claim 3.

7. A liquid ejecting head comprising the MEMS device according to claim 4.

8. A liquid ejecting apparatus comprising the liquid ejecting head according to claim 7.

9. A method of manufacturing the MEMS device according to claim 4, comprising steps of:
attaching the anisotropic conductive film formed on a flexible peeling film to the first substrate while at least one end of the anisotropic conductive film is located on a surface of the dummy terminal in the terminal arrangement direction of the connecting terminal array;
temporarily press-bonding the anisotropic conductive film to the connecting terminal array and the dummy terminal by heating and pressing the anisotropic conductive film between the peeling film and the first substrate by using a heat press-bonding tool;
peeling the peeling film from the anisotropic conductive film temporarily press-bonded to the connecting terminal array and the dummy terminal;
bonding the first substrate and the second substrate with the anisotropic conductive film interposed therebetween while a relative position between the first substrate and the second substrate are defined so that the connecting terminals of the connecting terminal array correspond to the connected terminals of the connected terminal array; and
press-bonding the first substrate and the second substrate by heating and pressing in a direction that sandwiches the anisotropic conductive film by using a heat press-bonding tool.

10. A method of manufacturing a liquid ejecting head comprising the method of manufacturing the MEMS device according to claim 9.

11. A method of manufacturing a liquid ejecting apparatus comprising the method of manufacturing the liquid ejecting head according to claim 10.
